(19) United States
(12) Patent Application Publication
(10) Pub. No.: US 2014/0308445 A1
(43) Pub. Date: Oct. 16, 2014

(54) CANISTER FOR DEPOSITION APPARATUS, AND DEPOSITION APPARATUS AND METHOD USING THE SAME

(71) Applicant: Samsung Display Co., Ltd., Yongin-city (KR)

(72) Inventors: Heung-Yeol Na, Yongin-city (KR); Ki-Yong Lee, Yongin-city (KR); Jin-Wook Seo, Yongin-city (KR); Min-Jae Jeong, Yongin-city (KR); Jong-Won Hong, Yongin-city (KR); Eu-Gene Kang, Yongin-city (KR); Seok-Rak Chang, Yongin-city (KR); Tae-Hoon Yang, Yongin-city (KR); Yun-Mo Chung, Yongin-city (KR); Byung-Soo So, Yongin-city (KR); Byoung-Keon Park, Yongin-city (KR); Ivan Maidanchuk, Yongin-city (KR); Dong-Hyun Lee, Yongin-city (KR); Kii-Won Lee, Yongin-city (KR); Won-Bong Baek, Yongin-city (KR); Jong-Ryuk Park, Yongin-city (KR); Bo-Kyung Choi, Yongin-city (KR); Jae-Wan Jung, Yongin-city (KR)

(21) Appl. No.: 14/318,086

(22) Filed: Jun. 27, 2014

Related U.S. Application Data
(62) Division of application No. 12/831,492, filed on Jul. 7, 2010.

(30) Foreign Application Priority Data
Jul. 7, 2009 (KR) 10-2009-0061715

(51) Int. Cl. C23C 16/455; C23C 16/52

(52) U.S. Cl. CPC C23C 16/45544; C23C 16/45525; C23C 16/52
USPC 427/255.395; 427/255.23

(57) ABSTRACT

A deposition apparatus, and a canister for the deposition apparatus capable of maintaining a predetermined amount of source material contained in a reactive gas supplied to a deposition chamber when the source material is deposited on a substrate by atomic layer deposition includes a main body, a source storage configured to store a source material, a heater disposed outside the main body, and a first feed controller configured to control the source material supplied to the main body from the source storage.

### CROSS-REFERENCE TO RELATED APPLICATIONS

This application is a divisional of U.S. patent application Ser. No. 12/831,492, filed on Jul. 7, 2010, and claims priority from and the benefit of Korean Patent Application No. 10-2009-0061715, filed on Jul. 7, 2009, each of which is hereby incorporated by reference for all purposes as if fully set forth herein.

### BACKGROUND OF THE INVENTION

1. Field of the Invention

An aspect of the present invention relates to a canister for a deposition apparatus, and a deposition apparatus and method using the same, and more particularly, to a canister for a is deposition apparatus capable of maintaining an amount of source material contained in a reactive gas supplied to a deposition chamber during deposition of the source material on a substrate like atomic layer deposition, and a deposition apparatus and method using the same.

2. Discussion of the Background

Since flat panel display devices are lightweight and thin, the flat panel display devices are used as alternatives to cathode-ray tube display devices. Examples of the flat panel display device include liquid crystal display (LCD) devices, and organic light emitting diode (OLED) display devices. Among these, the OLED display devices have high brightness and a wide viewing angle. In addition, since the OLED display devices do not need a back light, the OLED display devices can be implemented in ultra-thin structures.

The OLED display devices are classified into a passive matrix type and an active matrix type according to a driving method. The active matrix type OLED display device has a circuit using a thin film transistor (TFT).

The thin film transistor generally includes a semiconductor layer including a source region, a drain region and a channel region, a gate electrode, a source electrode and a drain electrode. The semiconductor layer may be formed of polycrystalline silicon (poly-Si) or amorphous silicon (a-Si). However, since electron mobility of the poly-Si is higher than that of the a-Si, the poly-Si is more frequently used.

One method of crystallizing a-Si into poly-Si is a crystallization method using a metal, which can crystallize a-Si into poly-Si in a very short period of time at relatively low temperature by depositing a metal catalyst on a substrate through sputtering or atomic layer deposition (ALD), and crystallizing the a-Si using the metal catalyst as a seed. Here, in the sputtering, deposition is performed by applying plasma to a metal target. In the atomic layer deposition, an atomic layer of the metal catalyst is formed on a substrate through a chemical method using a reactive gas including the metal catalyst.

To obtain a uniform crystal, in this crystallization method using the metal catalyst, a reactive gas has to be supplied to a deposition chamber with the same amount of metal catalysts as in every cycle of deposition. However, generally, a canister configured to supply the reactive gas to the deposition chamber produces a reactive gas formed by mixing a carrier gas with an evaporated source material such as the metal catalyst. The evaporated source material is formed by storing the source material such as the metal catalyst in a main body and heating the main body by an external heater in every cycle of deposition. Accordingly, the amount of the remaining source material in the main body and the amount of the evaporated source material according to the form or cross-section of the remaining source are changed, so that the amount of the source material contained in the reactive gas supplied to the deposition chamber cannot be uniformly maintained.

### SUMMARY OF THE INVENTION

Aspects of the present invention provide a canister for a deposition apparatus capable of maintaining a predetermined amount of source material contained in a reactive gas supplied to a deposition chamber from the canister, and a deposition apparatus and method using the same.

According to an aspect of the present invention, a canister for a deposition apparatus includes: a main body; a source storage configured to store a source material; a heater disposed outside the main body; and a first feed controller configured to control the source material supplied to the main body from the source storage.

According to another aspect of the present invention, a deposition apparatus includes: a deposition chamber; a canister configured to supply a reactive gas to the deposition is chamber; and a carrier gas feeder configured to supply a carrier gas to the canister. Here, the canister includes a main body, a heater, a source storage, and a first feed controller configured to control a source material supplied from the source storage to the main body.

According to still another aspect of the present invention, a deposition method includes: opening a first valve interposed between a main body and a source storage of a canister, and supplying a predetermined amount of source material to the main body; closing the first valve and evaporating the source material; supplying a carrier gas to the main body to be mixed with the evaporated source material; supplying a reactive gas formed by mixing the carrier gas with the evaporated source material to a deposition chamber; and depositing the source material on a substrate in the deposition chamber using the reactive gas.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a schematic diagram of a deposition apparatus according to an embodiment of the present invention.

### DETAILED DESCRIPTION OF THE ILLUSTRATED EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

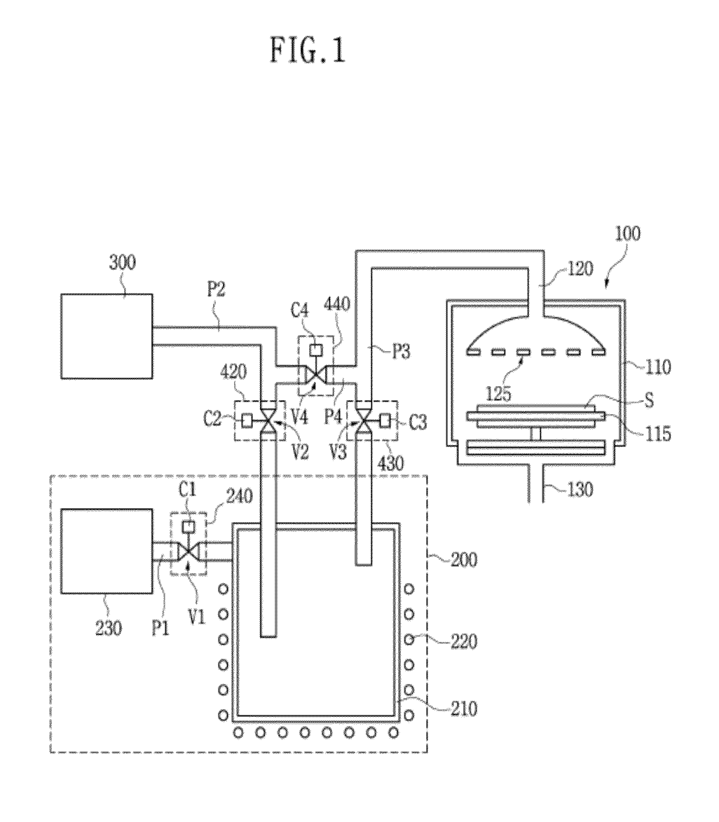

FIG. 1 is a schematic diagram of a deposition apparatus according to an aspect of the present invention. Referring to FIG. 1, the deposition apparatus includes a deposition chamber 100, a canister 200 configured to supply a reactive gas to the deposition chamber 100, and a carrier gas feeder 300 configured to supply a carrier gas to the canister 200.

The deposition chamber 100 includes a chamber main body 110, a shower head 125, a support chuck 115, and an outlet 130. The shower head 125 is connected with an inlet 120 which injects a reactive gas into the chamber main body 110 and is configured to uniformly spray the reactive gas on a substrate S The support chuck 115 is configured to support the substrate S. The outlet 130 is configured to exhaust the remaining reactive gas. Here, the deposition chamber 100 may be a chamber for atomic layer deposition (ALD). In order to facilitate the atomic layer deposition, the support chuck 115 may further include a temperature controller (not shown) configured to maintain the substrate S at a uniform temperature. However, the deposition chamber 100 can be used for other types of depositions.

The canister 200 evaporates a source material in every cycle of deposition and supplies the reactive gas to the deposition chamber 100. Here, the reactive gas is formed by mixing a carrier gas supplied from the carrier gas feeder 300 with the evaporated source material. The canister 200 includes a main body 210 configured to evaporate the source material, a heater 220 disposed outside the main body 210, a source storage 230 configured to store the source material, and a first feed controller 240 configured to control the amount of source material supplied to the main body 210. Here, the source material stored in the source storage 230 may be metal powder or liquid organic material used in the atomic layer deposition.

The first feed controller 240 includes a first valve V1 disposed on a first pipe P1 is connecting the main body 210 with the source storage 230, and a first controller C1 configured to control opening or closing of the first valve V1. Here, the first controller C1 controls the opening or closing the first valve V1 according to the amount of source material injected into the main body 210 through the first pipe P1, and may close the first valve V1 when the source material required for a first cycle of deposition in the deposition chamber 100 is supplied to the main body 210. The first controller C1 can include a sensor to detect the amount of source material or the sensor can be elsewhere located.

In a process of depositing the source material on the substrate S using the deposition apparatus described with reference to FIG. 1 according to an embodiment of the present invention, the first valve V1 of the first pipe P1 interposed between the main body 210 and the source storage 230 of the canister 200 is open to supply a predetermined amount of source material to the main body 210. Subsequently, the first valve V1 is closed to prevent the source material from being supplied to the main body 210, and then the source material is evaporated by the heater 220 disposed outside the main body 210. In an embodiment of the present invention, the source material has been described to be evaporated after the first valve V1 is closed. Alternatively, the source material may be evaporated while the source material is being supplied to the main body 210.

Afterward being evaporated, the carrier gas is supplied to the main body 210 through the second pipe P2 interposed between the main body 210 and the carrier gas feeder 300.

Thus, the reactive gas is formed by mixing the carrier gas with the evaporated source material within the main body 210. As shown, a second feed controller 420 configured to control the feed of the carrier gas is disposed on the second pipe P2 to prevent the carrier gas from being injected into the main body 210 when the source material is supplied to the main body 210.

While not required in all aspects, a third feed controller 430 is disposed at a third pipe P3 connecting the main body 210 with the deposition chamber 100 to prevent the source material from being evaporated in the main body 210 and the reactive gas from being supplied in an unstable state to the deposition chamber 100 during the formation of the reactive gas.

The shown second feed controller 420 includes a second valve V2 and a second controller C2 configured to control the opening or closing of the second valve V2. The shown third feed controller 430 includes a third valve V3 and a third controller C3 configured to control the opening or closing of the third valve V3.

The third valve V3 is open to supply the reactive gas, which is formed by mixing the evaporated source material with the carrier gas in the main body 210, to the deposition chamber 100. The reactive gas containing the source material is supplied to the deposition chamber 100 and is uniformly sprayed on the substrate S through the shower head 125 connected to the inlet 120 of the deposition chamber 100. The reactive gas containing the source material that is not deposited on the substrate S is exhausted to the outside of the deposition chamber 100 through the outlet 130.

In addition, the deposition apparatus according to a shown embodiment of the present invention includes a fourth pipe P4 connecting the carrier gas feeder 300 with the second valve V2 and the deposition chamber 100 with the third valve V3, and a fourth feed controller 440 disposed on the fourth pipe P4 in order to remove the reactive gas remaining in the deposition chamber 100 and the third pipe P3 after deposition. Here, similar to the second and third feed controllers 420 and 430, the shown fourth feed controller 440 includes a fourth valve V4 and a fourth controller C4 configured to control the opening or closing of the fourth valve V4.

According to another aspect of the present invention, a source storage 230 may be included in the canister 200 with a sufficient amount of source material for a single deposition process to be supplied to a main body 210 of the canister 200 from the source storage 230, thereby maintaining an environment of the canister 200 in which a source material is evaporated in every cycle of deposition and uniformly maintaining the amount of the source material contained in a reactive gas supplied by the canister 200.

While not required in all aspects, the controllers C1, C2, C3 and C4 can be implemented using mechanical controllers and/or using processors.

Although a few embodiments of the present invention have been shown and described, it would be appreciated by those skilled in the art that changes may be made in those embodiments without departing from the principles and spirit of the invention, the scope of which is defined in the claims and their equivalents.

What is claimed is:

1. A deposition method, comprising:
opening a first valve interposed between a main body and a source storage of a canister, and supplying a predetermined amount of source material to the main body;
closing the first valve after supplying the predetermined amount of the source material and evaporating the supplied source material in the main body;
supplying a carrier gas to the main body to be mixed with the evaporated source material;
supplying a reactive gas formed by mixing the carrier gas with the evaporated source material from the main body to a deposition chamber; and
depositing the source material contained in the reactive gas on a substrate in the deposition chamber.

2. The method according to claim 1, further comprising, after the deposition of the source material is completed, opening a fourth valve interposed in a fourth pipe between the carrier gas feeder and the deposition chamber to remove the reactive gas remaining in the deposition chamber through the fourth pipe connecting the deposition chamber with the main body.

3. The method according to claim 1, wherein the source material is deposited on the substrate by atomic layer deposition.

4. The method according to claim 1, wherein the source material includes metal powder.

5. The method according to claim 1, wherein the predetermined amount of the source material is an amount required for a single cycle of deposition in the deposition chamber.

6. The method according to claim 1, wherein the predetermined amount of the source material supplied to the main body is in an amount sufficient to perform a single deposition process.
